(19) United States
(12) Patent Application Publication
(10) Pub. No.: US 2025/0299926 A1
(43) Pub. Date: Sep. 25, 2025

(54) BIASABLE GAS DISTRIBUTION PLATE

(71) Applicant: Applied Materials, Inc., Santa Clara, CA (US)

(72) Inventors: Xianmin TANG, San Jose, CA (US); Kevin KASHEFI, Dublin, CA (US); John C. FORSTER, Mountain View, CA (US); Xiaodong WANG, San Jose, CA (US); Aravind KAMATH, Santa Clara, CA (US); Manjunath HV, Bangalore (IN); Mukund SUNDARARAJAN, Bangalore (IN); Cheng-Hsiung TSAI, Santa Clara, CA (US); Mianmian RUAN, Santa Clara, CA (US); Mostafa SHOUKRY, Hayward, CA (US)

(21) Appl. No.: 18/613,805

(22) Filed: Mar. 22, 2024

(51) Int. Cl. H01J 37/32; H01L 21/67

(52) U.S. Cl. CPC H01J 37/3244; H01J 37/32651; H01L 21/67017; H01J 2237/2007; H01J 2237/335

(57) ABSTRACT

Embodiments of the disclosure include a substrate processing system, comprising a biasable gas distribution plate disposed between a first volume and a second volume of a process chamber, wherein the biasable gas distribution plate comprises a first surface facing the first volume, a second surface facing the second volume, disposed opposite of the first surface, and a plurality of perforations extending between the first surface and the second surface. Some of the embodiments of the present disclosure provided herein provides an apparatus and method for performing a preclean process that utilizes a biasable gas distribution plate and supporting structure to enable preclean processes that can utilize chemically reactive reduction processes and/or physical sputtering processes as required by a particular device processing application.

### BACKGROUND

### Field

Embodiments of the present disclosure generally relate to an apparatus and methods employed in semiconductor substrate processing systems.

### Description of the Related Art

Substrate processing systems, such as plasma preclean chambers, may be used to clean a substrate prior to a subsequent processing step. For example, the substrate may be processed prior to entering the plasma preclean chamber, for example, the substrate may have been exposed to an etching process, an ashing process, or similar semiconductor process. Typically, the substrate will enter the plasma preclean chamber with residues, such as etch residues, oxides, or similar which are removed by exposing the substrate to plasma species generated in a plasma. Exposure of the substrate to the plasma species must be finely controlled in order to clean the substrate without damaging one or more portions of the substrate. Current methods lack the degree of control required to ensure cleaning without damage. Accordingly, new apparatus and methods are needed in the art.

### SUMMARY

Embodiments of the present disclosure generally relate to an apparatus and methods employed in semiconductor substrate processing systems. Further embodiments of the present invention are described below.

Embodiments of the present disclosure generally relate to a substrate processing system. The substrate processing system comprising: a biasable gas distribution plate, an upper inner shield, a lower inner shield, a distribution plate support, an isolation structure, a substrate support, a first power source, and a radio frequency (RF) power source. The biasable gas distribution plate being disposed between a first volume and a second volume of a process chamber, wherein the biasable gas distribution plate comprises a first surface facing the first volume, a second surface facing the second volume, disposed opposite of the first surface, and a plurality of perforations extending between the first surface and the second surface. The upper inner shield comprising an upper shield surface that is positioned over the first surface. The lower inner shield comprising a lower shield surface, wherein the second surface of the biasable gas distribution plate is positioned over the lower shield surface. The distribution plate support comprising a plate support feature, wherein the lower inner shield is disposed over plate support feature. The isolation structure disposed between the plate support feature and the second surface of the biasable gas distribution plate. The substrate support comprising a substrate supporting surface that is disposed in the second volume. The first power source coupled to the biasable gas distribution plate and configured to electrically bias the biasable gas distribution plate relative to a ground. The radio frequency (RF) power source coupled to an electrode, wherein the electrode is configured to generate a plasma in the first volume during processing in the process chamber when an RF signal is provided from the RF power source to the electrode.

Embodiments of the present disclosure also generally relate to a method of plasma processing, comprising: generating a plasma in a first volume of a processing chamber, wherein the processing chamber comprises: an upper inner shield disposed in the first volume; a lower inner shield disposed in a second volume for processing a substrate; a substrate support disposed in the second volume; and a biasable gas distribution plate disposed over a support feature of a distribution plate support in the process chamber and between the first volume and the second volume, wherein the biasable gas distribution plate comprises: a first surface facing the first volume; a second surface facing the second volume, disposed opposite of the first surface; and a plurality of perforations extending between the first surface and the second surface. While the plasma is generated, biasing the biasable gas distribution plate relative to the upper inner shield, wherein biasing the biasable gas distribution plate comprises applying a negative voltage to the biasable gas distribution plate.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 depicts schematic view of a substrate processing system in accordance with one or more embodiments described herein.

FIG. 2 depicts a perspective view of a biasable gas distribution plate of a substrate processing system in accordance with one or more embodiments described herein.

FIG. 3 depicts portions of a process kit in accordance with one or more embodiments described herein.

FIG. 4 depicts portions of a process kit in accordance with one or more embodiments described herein.

FIG. 5 depicts portions of a process kit in accordance with one or more embodiments described herein.

FIG. 6 depicts operations of a method in accordance with one or more embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to apparatus and methods employed in semiconductor substrate processing systems. The disclosure provided herein provides an apparatus and method for performing a preclean process that utilizes a biasable gas distribution plate and supporting structure to enable preclean processes that can utilize chemically reactive reduction processes and/or physical sputtering processes as required by a particular device processing application. One or more embodiments of the disclosed herein can be useful to prevent damage to fragile semiconductor structures, such as minimizing low-K damage during a preclean process.

### Example Substrate Processing System

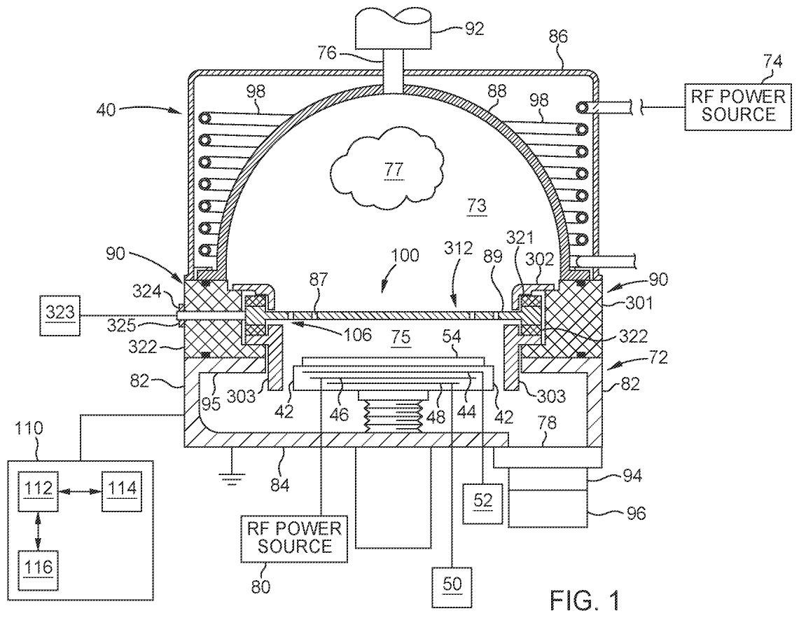

FIG. 1 depicts a substrate processing system 40. For example, in some embodiments, the substrate processing system 40 may be a pre-clean chamber available from Applied Materials, Inc., of Santa Clara, Calif. Other process chambers may also be modified in accordance with the teachings provided herein. Generally, the substrate processing system 40 comprises a processing chamber 72 having a first volume 73 and a second volume 75. The first volume 73 may include a portion of the processing chamber 72 where a plasma 77 is to be received (e.g., introduced or formed). The second volume 75 may include a portion of the processing chamber 72 where a substrate is to be processed with plasma species from the plasma 77. For example, a substrate support 42 may be disposed within the second volume 75 of the processing chamber 72. A biasable gas distribution plate 89 may be disposed in the processing chamber 72 between the first volume 73 and the second volume 75 such that the plasma 77 formed in the first volume 73 (or plasma species formed from the plasma 77) can only reach the second volume 75 by passing through the biasable gas distribution plate 89. Plasma species formed in the plasma 77 may include, but are not limited to, ions, electrons, reactants, or combinations thereof.

The substrate processing system 40 may include a gas inlet 76 coupled to the process chamber 72 to provide one or more processes gases that may be utilized to form a plasma 77 in the first volume. A gas exhaust 78 may be coupled to the processing chamber 72, for example in a lower portion of the process chamber 72 including the second volume 75. In some embodiments, an RF power source 74 may be coupled to an inductive coil 98 to generate the plasma 77 within the processing chamber 72. Alternatively, (not shown), the plasma may be generated remotely, for example, by a remote plasma source or the like, and flowed into the first volume 73 of the process chamber 72. In some embodiments, a power source 80 may be coupled to the substrate support 42 to control ion flux to a substrate 54 when present on a surface of the substrate support 42. The substrate processing system 40 may include a controller 110, for example, to control one or more components of the substrate processing system 40 to perform operations on the substrate 54. Other and further components and substrate processing system 40 are discussed below.

The process chamber 72 includes walls 82, a bottom 84, and a top 86. A dielectric lid 88 may be disposed under the top 86 and above a process kit 90, the process kit 90 coupled to the processing chamber 72 and configured to hold the biasable gas distribution plate 89. The dielectric lid 88 may be dome-shaped as illustrated in FIG. 1. The dielectric lid 88 be made from dielectric materials such as glass or quartz, and is typically a replaceable part that may be replaced after a certain number of substrates have been processed in the substrate processing system 40. The inductive coil 98 may be disposed about the dielectric lid 88 and coupled to an RF power source 74 to inductively couple RF power to the first volume 73 to form the plasma 77 in the first volume 73. Alternatively to or in combination with the inductive coil 98, a remote plasma source (not shown) may be used to form the plasma 77 in the first volume 73 or to provide the plasma 77 to the first volume 73.

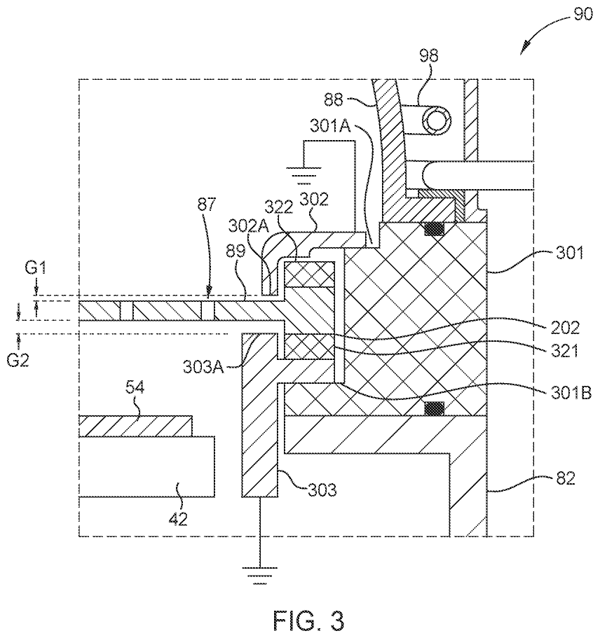

The process kit 90, described in FIGS. 3-5, rests on the wall 82 of the processing chamber 72. The process kit 90 may comprise any suitable materials compatible with processes being run in the substrate processing system 40. The components of the process kit 90 may contribute to defining the first volume 73 and the second volume 75. For example, the first volume 73 is defined by the upper suface of the biasable gas distribution plate 89 and the inner surface of the dielectric lid 88. For example, the second volume 75 may be defined the lower surface of the biasable gas distribution plate 89 and the substrate supporting surface of the substrate support 42.

### Example Biasable Gas Distribution Plate

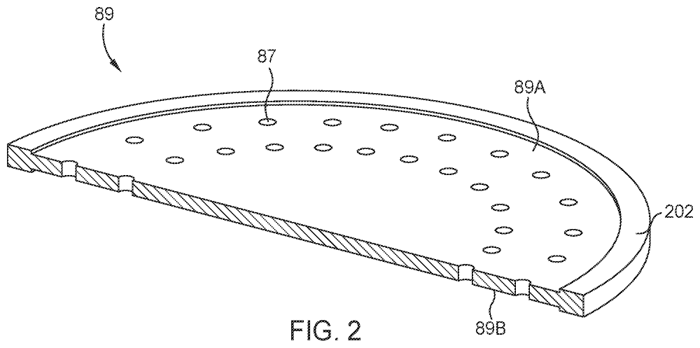

FIG. 2 depicts a perspective view of the biasable gas distribution plate (BGDP) 89 in accordance with some embodiments of the present invention. The biasable gas distribution plate 89 includes a mounting flange 202. In one embodiment the mounting flange 202 is raised from the first surface 89A and the second surface 89B. In some embodiments, the mounting flange 202 is extends from the first surface 89A and the second surface 89B. In other embodiments, the mounting flange 202 may be position above, below, or coplanar with the first surface 89A, the second surface 89B, or any combination thereof. In some embodiments, the mounting flange 202 may be a monolithic part formed with the biasable gas distribution plate 89. In other embodiments, the mounting flange 202 may be a separate part. The biasable gas distribution plate 89 may be fabricated of a conductive material such as a metal, metal doped ceramic material, or other conductive materials. In one example, the biasable gas distribution plate 89 comprises stainless steel, titanium, or aluminum. In another example, the biasable gas distribution plate 89 comprises a coated metal material, such as an electroless nickel plated aluminum plate or an anodized aluminum plate. In some embodiments, the biasable gas distribution plate 89 could comprise a conductive material containing screen or mesh wherein the open area of the screen or mesh corresponds to the desired open area provided by the perforations 87. Alternatively, a combination of a plate and screen or mesh may also be utilized.

The biasable gas distribution plate 89 includes a plurality of perforations 87 disposed through the biasable gas distribution plate 89, extending from the first surface 89A facing the first volume 73 to the second surface 89B facing the second volume 75. The plurality of perforations 87 include a first pattern of two or more perforations arranged along a circular path disposed over a peripheral region of the substrate support 42. In some embodiments, the peripheral region of the substrate support 42 includes the area that is defined between about 50% to about 100% of a radius of a circular shaped biasable gas distribution plate 89. The first pattern includes one or more concentric rows of perforations where each row of the one or more rows is spaced radially from a center of the biasable gas distribution plate and where each row includes at least one perforation. The plurality of perforations 87 fluidly couple the first volume 73 to the second volume 75. The biasable gas distribution plate 89 may be used to limit the flow of plasma species generated in the first volume 73 to the second volume 75. For example, plasma species flow may be tailored to a desired level by controlling pattern and characteristics of the perforations formed in the biasable gas distribution plate 89. For example, the plurality of perforations 87 may vary in size, spacing, and/or geometric arrangement across the surface of the biasable gas distribution plate 89. The diametral size of the perforations 87 generally range from 0.050 inches to about 0.50 inches. In some embodiments, the perforations a have a diameter to height (e.g., thickness of the biasable gas distribution plate) aspect ratio that is between 1:1 and 1:2. The perforations 87 may be arranged to define an open area in the surface of the biasable gas distribution plate 89 of from about 2% to about 25%. It is contemplated that the holes may be arranged in other geometric or random patterns utilizing other size holes or holes of various sizes. The size, shape, and patterning of the holes may vary depending upon the desired ion density over the surface of the substrate disposed in the second volume 75. For example, more holes of small diameter and/or higher aspect ratio may be used to increase the radical to ion density ratio in the second volume 75. In other situations, a number of larger holes may be interspersed with small holes to increase the ion to radical density ratio in the second volume 75. Alternatively, the larger holes may be positioned in specific areas of the biasable gas distribution plate 89 to contour the ion distribution over the surface of the substrate disposed in the second volume 75.

Alternatively, or in combination, and for example, the positioning of each perforation 87 on the biasable gas distribution plate 89 may be selected to achieve a desired distribution of ions and/or radicals provided into the second volume 75. For example, the positioning of the perforations may be selected to correspond with the density of the plasma 77 formed in the first volume 73, such as if the plasma 77 were to have a higher ion density proximate the center and a lower ion density proximate the edge of the chamber. For example, any such non-uniformity in the plasma 77 (if one existed) could be accounted for, such as by having a higher density of openings proximate the center of the biasable gas distribution plate 89 and a lower density proximate the edge of the biasable gas distribution plate 89. Accordingly, the density of perforations 87 in the plurality of perforations 87 may be selected to be sufficient to reduce the flow of plasma species generated in the plasma 77 as the plasma 77 moves from the first volume 73 to the second volume 75.

Other aspects of the biasable gas distribution plate 89 may be used to adjust the flow of plasma species of the plasma 77. Alternatively, or in combination with aspects discussed above, and for example, the diameter and aspect ratio of each circular shaped perforation 87 in the plurality of perforations 87 may be selected to be sufficient to reduce the flow of plasma species in the plasma 77 as the plasma 77 move from the first volume 73 to the second volume 75. For example, the perforations 87 may limit the flow of plasma species which can reach the second volume 75, if the diameter of each perforation 87 is less than the plasma sheath width formed thereover. Alternatively, or in combination with aspects discussed above, and for example, the thickness of the biasable gas distribution plate 89 may be adjusted, such as to change the length of each perforation 87, and thus aspect ratio, to control flow of a type of plasma species (i.e., ions or radicals) provided through the biasable gas distribution plate 89. The perforations 87 may allow radicals and other neutral gas species to reach the second volume 75 and enable processing of a substrate present on the substrate support 42. Further, the biasable gas distribution plate 89 may be placed sufficiently far above the substrate support 42, either by location of the lip 104 and/or by position of the surface of the substrate support 42 relative to the biasable gas distribution plate 89 to allow diffusion to smear out any impact of a pattern of the plurality of perforations 87 on a substrate disposed on the substrate support 42 due to the flow of the process gases provided from the gas supply 92.

Returning to the substrate processing system 40, the gas inlet 76 is connected to a processing gas supply 92 and introduces the processing gas into the substrate processing system 40 during processing. As illustrated, the gas inlet 76 is coupled to the first volume 73 via the dielectric lid 88. However, the gas inlet 76 may be coupled into the first volume 73 at any suitable location. The gas exhaust 78 may comprises a servo control throttle valve 94 and a vacuum pump 96. The vacuum pump 96 evacuates the substrate processing system 40 prior to processing. During processing, the vacuum pump 96 and the servo control throttle valve 94 maintain the desired pressure within the substrate processing system 40 during processing. In some embodiments, the process gas may comprise one or more of hydrogen (H₂), helium (He), argon (Ar), nitrogen (N₂) or the like. In some embodiments, the process gas comprises a mixture of H₂ and He, wherein H₂ is about 5%.

The substrate support 42 generally includes one or more of a heater 44, an RF electrode 46, and a chucking electrode 48. For example, the RF electrode 46 may comprise titanium, tungsten, or other metal and may be connected to a power source 80 to provide an RF bias during processing. The use of bias power to the RF electrode 46 may aid in plasma ignition and/or control of ion current. However, bias power from the RF electrode 46 may not be compatible with all embodiments of the substrate processing system 40. Accordingly, plasma ignition must be achieved by other means in such cases. For example, at sufficiently high pressure (depending on gas type), the capacitive coupling between the inductive coil 98, and the first volume 73 can enable plasma ignition.

The substrate support 42 may include the chucking electrode 48 to secure the substrate 54 when disposed on the substrate support to the surface of the substrate support 42. The chucking electrode 48 may be coupled to a chucking power source 50 through a matching network (not shown). The chucking power sources 50 may be capable of producing up to 12,000 Watts at a frequency of about 2 MHZ, or about 13.56 MHz, or about 60 MHz. In some embodiments, the chucking power source 50 may provide either continuous or pulsed AC or DC power. In some embodiments, the chucking power source may be a DC or pulsed DC source.

The substrate support may include the heater 44 to heat the substrate 54 when disposed on the substrate support 42 to a desired temperature. The heater 44 may be any type of heater suitable to provide control over the substrate temperature. For example, the heater 44 may be a resistive heater. In such embodiments, the heater 44 may be coupled to a power source 52 configured to provide the heater 44 with power to facilitate heating the heater 44. In some embodiments, the heater 44 may be disposed above or proximate to the surface of the substrate support 42. Alternatively, or in combination, in some embodiments, the heaters may be embedded within the substrate support 42. The number and arrangement of the heater 44 may be varied to provide additional control over the temperature of the substrate 54. For example, in embodiments where more than one heater is utilized, the heaters may be arranged in a plurality of zones to facilitate control over the temperature across the substrate 54, thus providing increased temperature control.

The controller 110 comprises a central processing unit (CPU) 112, a memory 114, and support circuits 116 for the CPU 112 and facilitates control of the components of the substrate processing system 40 and, as such, methods of processing a substrate in the substrate processing system 40. The controller 110 may be one of any form of general-purpose computer processor that can be used in an industrial setting for controlling various chambers and sub processors. The memory, or computer-readable medium, 114 of the CPU 112 may be one or more of readily available memory such as random access memory (RAM), read only memory (ROM), floppy disk, hard disk, or any other form of digital storage, local or remote. The support circuits 116 are coupled to the CPU 112 for supporting the processor in a conventional manner. These circuits include cache, power supplies, clock circuits, input/output circuitry and subsystems, and the like. The memory 114 stores software (source or object code) that may be executed or invoked to control the operation of the substrate processing system 40 in the manner described herein. The software routine may also be stored and/or executed by a second CPU (not shown) that is remotely located from the hardware being controlled by the CPU 112.

In an example of operation, the substrate 54 is positioned on the substrate support 42, and the substrate processing system 40 is evacuated to provide a vacuum processing environment. A processing gas is introduced through the gas inlet 76 into the first volume 73. To activate the reaction, a plasma of the processing gas is generated in the processing region through inductive coupling and/or capacitive coupling.

### Process Kit Example

FIG. 3 depicts portions of a process kit 90 in accordance with one or more embodiments described herein. The process kit 90 includes a biasable gas distribution plate support 301. The biasable gas distribution plate support 301 is disposed between the walls 82 and the dielectric lid 88. In some embodiments, the biasable gas distribution plate support 301 is coupled to an electrical ground. The biasable gas distribution plate support 301 acts as an adaptor to support the process kit components in the processing chamber 72. The biasable gas distribution plate support 301 includes a support feature 301A and a support feature 301B.

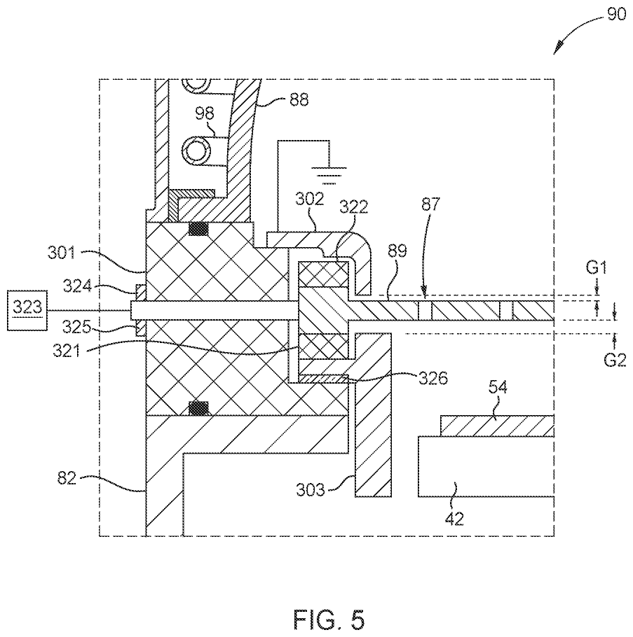

The process kit 90 includes a lower inner shield 303. The lower inner shield 303 is disposed in the second volume on the support feature 301B of the biasable gas distribution plate support 301. In one embodiment, a portion of the lower inner shield 303 extends below the biasable gas distribution plate support 301. In some embodiments, a portion of the lower inner shield does not extend below the biasable gas distribution plate support 301. The lower inner shield 303 may be formed of any suitable material including, but not limited to, a metal, metal doped or coated ceramic material, or other conductive materials. In one example, the lower inner shield 303 comprises stainless steel, titanium, or aluminum. In one embodiment, the lower inner shield 303 is electrically grounded. In some embodiments, the lower inner shield 303 can be biased, by use of a power source (not shown), relative to the biasable gas distribution plate 89 and/or the biasable gas distribution plate support 301. In other embodiments, as depicted in FIG. 5, the lower inner shield 303 may be electrically floating.

The process kit 90 includes one or more one or isolation structures. Each isolation structure of the one or more isolation structures may be formed of any suitable dielectric material including, but not limited to, a ceramic materials such as alumina. Each isolation structure of the one or more isolation structures is configured to electrically isolate the biasable gas distribution plate 89 disposed between the one or more isolation structures. The one or more isolation structures include at least a first isolation structure 321 and a second isolation structure 322. The first isolation structure 321 is disposed above the lower inner shield 303. The first isolation structure 321 is configured to support the mounting flange 202 of the biasable gas distribution plate 89 above the lower inner shield 303. In one embodiment, the biasable gas distribution plate 89 is not affixed to the first isolation structure 321, process chamber 72, or process kit 90, leaving the biasable gas distribution plate 89 physically floating above the first isolation structure 321. By leaving the biasable gas distribution plate 89 floating, the biasable gas distribution plate 89 can expand and contract without restraint during processing due to changes in its temperature during processing, reducing the chance of material failure in the biasable gas distribution plate 89. The first isolation structure 321 is further configured to leave a second gap G2 formed between a lower shield surface 303A of the lower inner shield 303 and the biasable gas distribution plate 89. The second gap G2 is typically configured to be equal to or smaller than the plasma dark space formed during processing, or space in which a plasma is unable to form during processing due to the size of gap between the components. For example, the second gap G2 is about 0.05 inches to about 0.25 inches. In embodiments where the lower inner shield 303 is electrically floating, the second gap may be smaller than the plasma dark space. The second isolation structure 322 is disposed above biasable gas distribution plate 89.

The process kit 90 includes an upper inner shield 302. The upper inner shield 302 is disposed in the first volume 73 on the support feature 301A of the biasable gas distribution plate support 301. A portion of the upper inner shield 302 extends over the top and a side surface of the second isolation structure 322. The upper inner shield 302 is configured to maintain a first gap G1 between an upper shield surface 302A of the upper inner shield 302 and the biasable gas distribution plate 89. The upper inner shield 302 is further configured to maintain the first gap G1 between the upper inner shield 302 and the second isolation structure 322. The first gap G1 is smaller than the plasma dark space. For example, the first gap G1 is about 0.05 inches to about 0.25 inches. The upper inner shield 302 may be formed of any suitable material including, but not limited to, a metal, metal doped or coated ceramic material, or other conductive materials. In one example, the upper inner shield 302 comprises stainless steel, titanium, or aluminum. In one embodiment, the upper inner shield 302 is electrically grounded. In some embodiments, the upper inner shield 302 can be biased, by use of a power source (not shown), relative to the biasable gas distribution plate 89. In other embodiments, the upper inner shield 302 may be electrically floating.

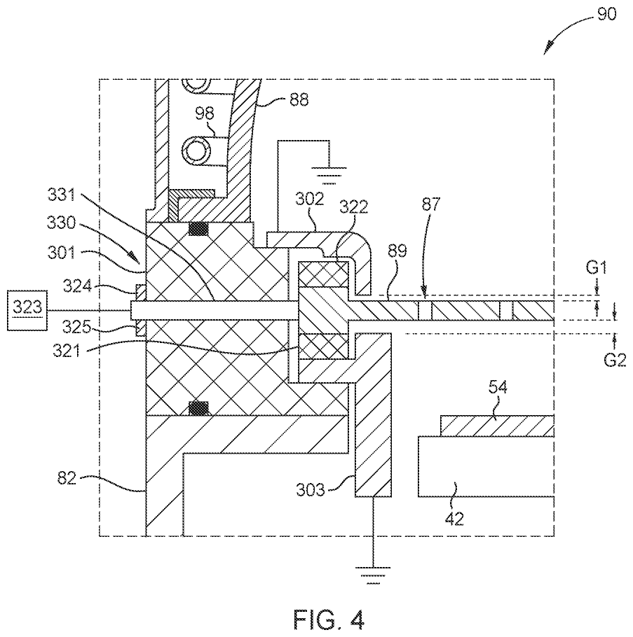

As depicted in FIG. 4, the process kit 90 will include an electrical power feedthrough assembly 330. The electrical power feedthrough assembly 330 will include an electrical power feedthrough 331, which is coupled to an electrical power feedthrough source 323, that is disposed through the biasable gas distribution plate support 301. The electrical power feedthrough 331 is electrically coupled to the biasable gas distribution plate 89 and electrically coupled to a power source 323. The electrical power feedthrough 331 allows the biasable gas distribution plate 89 to be electrically biased relative to upper inner shield 302 with a positive or negative voltage. By biasing the biasable gas distribution plate 89, the flow of plasma species, such as ions, generated in the first volume 73 to the second volume 75 may be reduced, increased, or halted. In some embodiments, an electrical feedthrough 324 is coupled to an end of the electrical power feedthrough 331, and is configured to form a vacuum seal between a sealing plate 325 of the electrical feedthrough 324 and a surface of the biasable gas distribution plate support 301.

As depicted in FIG. 5, the process kit may 90 may also include an dielectric isolator 326 disposed between the biasable gas distribution plate support 301 and the lower inner shield 303. In some embodiments, the process kit 90 may include additional sealing elements that used in conjunction with the dielectric isolator 326.

### Process Sequence Example

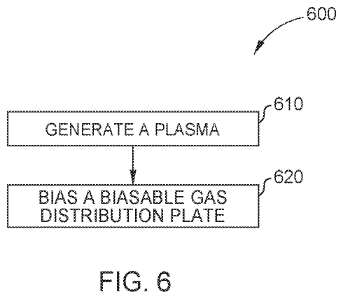

FIG. 6 depicts a method 600 according to embodiments described herein. Method 600 includes operations 610 and 620.

Operation 610 of method 600 includes generating a plasma 77 in a first volume 73 of a process chamber 72. The first volume 73 includes an upper inner shield 302 and the second volume 75 includes a lower inner shield 303. The first volume 73 is separated from the second volume 75 by a biasable gas distribution plate 89 disposed on a support feature 301B of a biasable gas distribution plate support 301 disposed in the process chamber 72 between the first volume 73 and the second volume 75.

Operation 620 of method 600 includes biasing the biasable gas distribution plate 89 relative to the upper inner shield 302. Biasing the biasable gas distribution plate 89 relative to the upper inner shield 302 in operation 620 may include delivering a negative voltage relative to the upper inner shield 302 and/or ground from the power source 80 to the biasable gas distribution plate 89 via the electrical power feedthrough 331 which is electrically coupled to the biasable gas distribution plate 89, and electrically coupled to the power source 323. Biasing the biasable gas distribution plate 89 relative to the upper inner shield 302 in operation 620 may include delivering a positive voltage relative to ground to the biasable gas distribution plate 89. In some embodiments, operation 620 of method 600 may additionally include biasing the biasable gas distribution plate 89 relative to the lower inner shield 303. In other embodiments, operation 620 of method 600 may additionally include biasing the biasable gas distribution plate 89 relative to the substrate support.

By biasing the biasable gas distribution plate 89 relative to the upper inner shield, the flow of plasma species generated in the first volume 73 to the second volume 75 may be reduced, increased, or halted. In some embodiments, it is desirable to generate a first voltage bias having a first bias value during a first period of the process recipe and a second voltage bias having a second bias value during a second period of the process recipe. The first and second periods may be sequentially repeated multiple times during a process recipe. In some embodiments, at least one of the first voltage bias and the second voltage bias include pulsed voltage waveform that includes a series of voltage pulses that are provided at a pulsing frequency. In some embodiments, the first voltage bias and the second voltage bias both include a negative DC bias or both include a positive DC bias In some embodiments, the first bias value has a greater negative value than the second bias value to control the initial plasma generation in the first volume 73. In some other embodiments, the first voltage bias includes a negative DC bias and the second voltage bias maintains a ground level bias or even positive bias. In yet some other embodiments, the first voltage bias includes a ground level bias or positive bias and the second voltage bias maintains a negative bias.

### ADDITIONAL CONSIDERATIONS

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined, or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

As used herein, “a CPU”, “controller”, “a processor”, “at least one processor”, or “one or more processors”, generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation. Similarly, “a memory”, at least one memory”, or “one or more memories”, generally refers to a single memory configured to store data and/or instructions, multiple memories configured to collectively store data and/or instructions.

As used herein, “gas” and “fluid” may be used interchangeable with either term generally referring to elements, compounds, materials, etc., having the properties of a gas, a fluid, or both a gas and a fluid.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward,” “horizontal,” “vertical,” and the like do not refer to absolute directions. Instead, these terms refer to directions relative to a nonspecific plane of reference. This non-specific plane of reference may be vertical, horizontal, or other angular orientation.

The singular forms “a”, “an”, and “the”, include plural referents, unless the context clearly dictates otherwise. Within a claim, reference to an element in the singular is not intended to mean “one and only one” unless specifically so stated, but rather “one or more”. Unless specifically stated otherwise, the term “some” refers to one or more.

Embodiments of the present disclosure may suitably “comprise”, “consist”, or “consist essentially of”, the limiting features disclosed, and may be practiced in the absence of a limiting feature not disclosed. As used here and in the appended claims, the words “comprise”, “has”, and “include”, and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

“Coupled” and “coupling” means that the subsequently described material is connected to previously described material. The connection may be a direct, or indirect connection, and may, or may not, include intermediary components such as plumbing, wiring, fasteners, mechanical power transmission, electrical communication, wired and/or wireless transmission, etc., which may suitable to affect operation of the components.

As used, the term “determining” encompasses a wide variety of actions. For example, “determining” may include calculating, computing, processing, deriving, investigating, looking up, for example, looking up in a table, a database, or another data structure, and ascertaining. In addition, “determining” may include receiving, for example, receiving information, and accessing, for example, accessing data in a memory. In addition, “determining” may include resolving, selecting, choosing, and establishing.

When the word “approximately” or “about” are used, this term may mean that there may be a variance in value of up to +10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112 (f), for any limitations of any of the claims, except for those in which the claim expressly uses the words ‘means for’ together with an associated function.

The following claims are not intended to be limited to the embodiments provided but rather are to be accorded the full scope consistent with the language of the claims.

What is claimed is:

1. A substrate processing system, comprising:
a biasable gas distribution plate disposed between a first volume and a second volume of a process chamber, wherein the biasable gas distribution plate comprises:
a first surface facing the first volume;
a second surface facing the second volume, disposed opposite of the first surface; and
a plurality of perforations extending between the first surface and the second surface;
an upper inner shield comprising an upper shield surface that is positioned over the first surface;
a lower inner shield comprising a lower shield surface, wherein the second surface of the biasable gas distribution plate is positioned over the lower shield surface;
a distribution plate support comprising a plate support feature, wherein the lower inner shield is disposed over plate support feature;
an isolation structure disposed between the plate support feature and the second surface of the biasable gas distribution plate;
a substrate support comprising a substrate supporting surface that is disposed in the second volume;
a first power source coupled to the biasable gas distribution plate and configured to electrically bias the biasable gas distribution plate relative to a ground; and
a radio frequency (RF) power source coupled to an electrode, wherein the electrode is configured to generate a plasma in the first volume during processing in the process chamber when an RF signal is provided from the RF power source to the electrode.

2. The substrate processing system of claim 1, wherein the plurality of perforations comprise:
a first pattern of two or more perforations arranged along a circular path disposed over a peripheral region of the substrate support disposed in the second volume, the first pattern further comprising:
one or more concentric rows of perforations, wherein each row of the one or more concentric rows is spaced radially from a center of the biasable gas distribution plate,
each row of the one or more concentric rows include at least one perforation, and
each of the plurality of perforations extends from the first volume to the second volume.

3. The substrate processing system of claim 1, wherein the electrode comprises one or more inductive coils disposed around the first volume.

4. The substrate processing system of claim 1, wherein the upper inner shield is electrically coupled to ground.

5. The substrate processing system of claim 4, wherein
a first gap is formed between the upper shield surface and the first surface, and
the first gap is sized to form a dark space.

6. The substrate processing system of claim 1, wherein the upper inner shield is electrically isolated from the ground.

7. The substrate processing system of claim 1, wherein the lower inner shield is electrically isolated from the ground.

8. The substrate processing system of claim 1, wherein the lower inner shield is disposed on the plate support feature.

9. The substrate processing system of claim 1, wherein an electrode in the substrate support is coupled to a power source.

10. The substrate processing system of claim 1, further comprising:
a first gap formed between the biasable gas distribution plate and the upper inner shield; and
a second gap between the biasable gas distribution plate and the lower inner shield, wherein the first gap and second gap are less than a plasma dark space.

11. The substrate processing system of claim 1, wherein the biasable gas distribution plate rests on to the isolation structure.

12. The substrate processing system of claim 1, wherein the plurality of perforations are disposed within a peripheral region and further comprise:
concentric rows of perforations, wherein each row of the concentric rows is spaced radially from a center of the biasable gas distribution plate.

13. The substrate processing system of claim 12, further comprising an electrical power feedthrough, wherein the electrical power feedthrough is electrically coupled to the biasable gas distribution plate, and electrically coupled to a power source.

14. A method of plasma processing, comprising:
generating a plasma in a first volume of a processing chamber, wherein the processing chamber comprises:
an upper inner shield disposed in the first volume;
a lower inner shield disposed in a second volume for processing a substrate;
a substrate support disposed in the second volume; and
a biasable gas distribution plate disposed over a support feature of a distribution plate support in the process chamber and between the first volume and the second volume, wherein the biasable gas distribution plate comprises:
a first surface facing the first volume;
a second surface facing the second volume, disposed opposite of the first surface; and
a plurality of perforations extending between the first surface and the second surface; and
biasing the biasable gas distribution plate relative to the upper inner shield, wherein biasing the biasable gas distribution plate comprises applying a negative voltage to the biasable gas distribution plate.

15. The method of claim 14, wherein generating a plasma in a first volume of a processing chamber comprises delivering radio-frequency (RF) power from an RF power source to one or more inductive coils disposed around the first volume.

16. The method of claim 14, wherein the processing chamber further comprises an electrical power feedthrough, wherein the electrical power feedthrough is electrically coupled to the biasable gas distribution plate, and electrically coupled to a power source.

17. The method of claim 14, wherein biasing the biasable gas distribution plate comprises delivering a negative voltage to the biasable gas distribution plate.

18. The method of claim 14, wherein biasing the biasable gas distribution plate includes delivering a positive voltage to the biasable gas distribution plate.

19. The method of claim 14, further comprising biasing an electrode within the substrate support.
